(19) United States
(12) Patent Application Publication
(10) Pub. No.: US 2007/0298594 A1
(43) Pub. Date: Dec. 27, 2007

(54) Semiconductor device fabrication method

(76) Inventors: Ichiro Mizushima, Yokohama-shi (JP); Kiyotaka Miyano, Tokyo (JP); Katsuaki Natori, Yokohama-shi (JP); Yoshio Ozawa, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/806,926

(22) Filed: Jun. 5, 2007

(30) Foreign Application Priority Data
Jun. 6, 2006 (JP) 2006-157638

(51) Int. Cl. H01L 21/36

(52) U.S. Cl. 438/479; 257/E21.461

(57) ABSTRACT

A semiconductor device fabrication method includes forming an insulating film having an opening on the major surface of single-crystal silicon, and forming an amorphous silicon film on the surface of the single-crystal silicon exposed in the opening and on the surface of the insulating film. The semiconductor device fabrication method further includes performing annealing to change the amorphous silicon film into a single crystal, and forming a single-crystal silicon film, SiGe film, or carbon-containing silicon film by vapor phase growth on a region where the amorphous silicon film is changed into a single crystal.

### CROSS-REFERENCE TO RELATED APPLICATIONS

This application is based upon and claims the benefit of priority from prior Japanese Patent Application No. 2006-157638, filed Jun. 6, 2006, the entire contents of which are incorporated herein by reference.

### BACKGROUND OF THE INVENTION

1. Field of the Invention

The present invention relates to a semiconductor device fabrication method of forming a thin single-crystal silicon film on an insulating film.

2. Description of the Related Art

The formation of a MOSFET on a thin single-crystal film formed on an insulating film, i.e., on a so-called SOI (Silicon On Insulator) is one of the useful device formation methods in respect of, e.g., the ease with which the short-channel effect is inhibited. However, the conventional SOI is formed by a special method called SIMOX (Silicon IMplanted OXide) or smart cut.

Lateral Solid phase epitaxy is a method to obtain the SOI structure without preparing any special substrates. In order to obtain a single crystalline layer by lateral solid phase epitaxy, amorphous silicon is deposited on the surface of a silicon substrate covered with an insulating film and partially exposed, and changed into a single crystal from the opening as a seed (examples are Jpn. Pat. Appln. KOKAI Publication Nos. 2-208920 and 2-211616 and Japanese Patent No. 2994667).

Unfortunately, the size of the single-crystal region obtained by lateral solid phase epitaxy is normally limited to the range of a few μm from the opening. Formation of a polycrystalline silicon region caused by the generation of heterogeneous nucleation inhibits the formation of a single crystalline region by lateral solid phase epitaxy. Thus, a single crystalline region is limited in the range of a few μm. Another reason is that the rate of lateral solid phase epitaxy delays during the lateral growth.

### BRIEF SUMMARY OF THE INVENTION

According to a first aspect of the present invention, there is provided a semiconductor device fabrication method comprising forming an insulating film having an opening on a major surface of single-crystal silicon, forming an amorphous silicon film on a surface of the single-crystal silicon exposed in the opening and on a surface of the insulating film, performing annealing to change the amorphous silicon film into a single crystal, and forming one of a single-crystal silicon film, an SiGe film, and a carbon-containing silicon film by vapor phase growth on a region where the amorphous silicon film is changed into a single crystal.

According to a second aspect of the present invention, there is provided a semiconductor device fabrication method comprising forming an insulating film having an opening on a major surface of single-crystal silicon, forming a first single-crystal silicon film on a surface of the single-crystal silicon exposed in the opening, forming an amorphous silicon film on the insulating film and the first single-crystal silicon film, performing annealing to change the amorphous silicon film into a single crystal, and forming one of a second single-crystal silicon film, an SiGe film, and a carbon-containing silicon film by vapor phase growth on a region where the amorphous silicon film is changed into a single crystal.

### BRIEF DESCRIPTION OF THE SEVERAL VIEWS OF THE DRAWING

FIG. 1 is a sectional view showing a semiconductor device fabrication method according to the first embodiment of the present invention;

FIG. 2 is a sectional view showing the semiconductor device fabrication method following FIG. 1;

FIG. 3 is a sectional view showing the semiconductor device fabrication method following FIG. 2;

FIG. 4 is a sectional view showing a semiconductor device fabrication method according to the second embodiment of the present invention;

FIG. 5 is a sectional view showing a semiconductor device fabrication method according to the third embodiment of the present invention;

FIG. 6 is a sectional view showing the semiconductor device fabrication method following FIG. 5;

FIG. 7 is a sectional view showing the semiconductor device fabrication method following FIG. 6;

FIG. 8 is a sectional view showing the semiconductor device fabrication method following FIG. 7;

FIG. 9 is a sectional view showing another semiconductor device fabrication method according to the third embodiment of the present invention;

FIG. 10 is a sectional view showing the semiconductor device fabrication method following FIG. 9;

FIG. 11 is a sectional view when a NAND cell is formed using the structure shown in FIG. 10;

FIG. 12 is a sectional view when a MOSFET is formed using the structure shown in FIG. 10;

FIG. 13 is a sectional view showing a semiconductor device fabrication method according to the fourth embodiment of the present invention; and

FIG. 14 is a sectional view showing the semiconductor device fabrication method following FIG. 13.

### DETAILED DESCRIPTION OF THE INVENTION

Embodiments of the present invention will be explained in detail below with reference to the accompanying drawing.

### First Embodiment

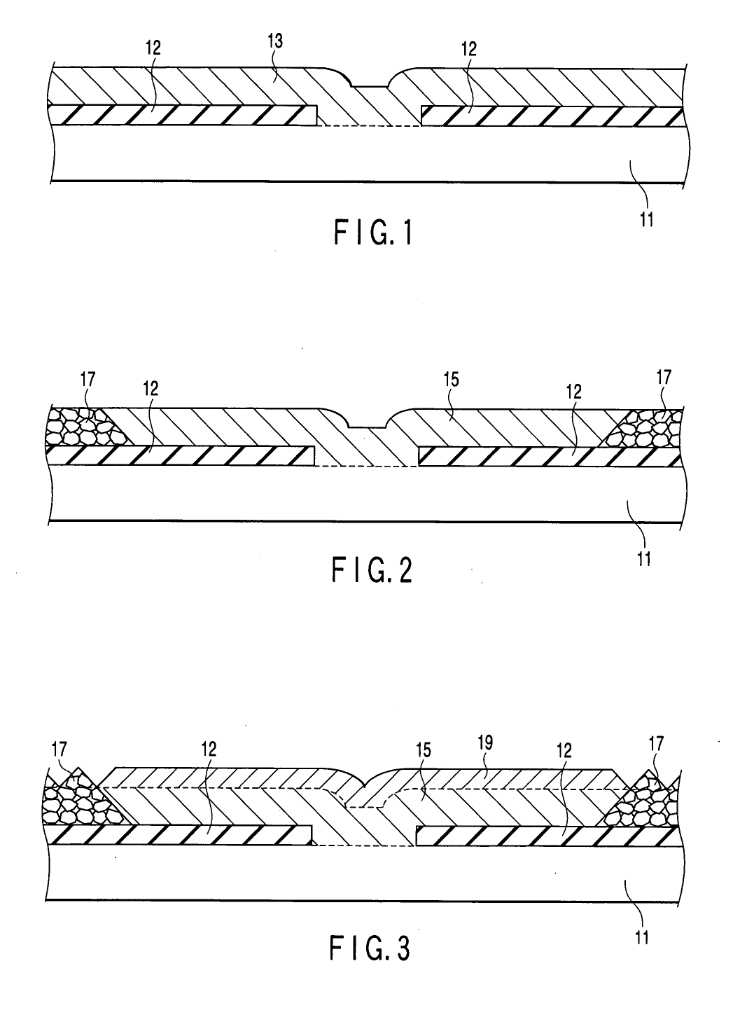

A semiconductor device fabrication method according to the first embodiment of the present invention will be explained below with reference to sectional views of FIGS. 1 to 3.

First, as shown in FIG. 1, a 10-nm thick insulating film 12 such as a silicon oxide film having an opening is formed on the major surface of a silicon substrate 11 (single-crystal silicon). More specifically, the silicon oxide film 12 is deposited on the silicon substrate 11 by thermally decomposing, e.g., TEOS (Tetra Ethylortho Silicate) by CVD, and a resist is formed by coating and patterned to form an opening after that. This exposes the surface of the silicon substrate 11 in the opening.

Then, on the surface of the exposed silicon substrate 11 (single-crystal silicon) and on the surface of the silicon oxide film 12, a 50-nm thick amorphous silicon film 13 is deposited at a deposition temperature of 580° C. by low-pressure CVD using monosilane (SiH₄) (FIG. 1).

As shown in FIG. 2, the amorphous silicon film 13 is changed into a single crystal by lateral solid phase epitaxy by performing annealing at 620° C. for 30 min, thereby forming a single-crystal silicon region 15 around the opening. A region that is not changed into a single crystal forms a polysilicon region 17.

After that, as shown in FIG. 3, vapor phase growth is performed on the single-crystal silicon region 15 at a pressure of 10 Torr (˜1,330 Pa) and a temperature of 780° C. by using a gas mixture of, e.g., dichlorosilane (SiH₂Cl₂) (flow rate=100 sccm) and hydrochloric acid (HCl) (flow rate=40 sccm). The flow rate unit “sccm” (standard cubic centimeter per minute) is the volume (cc) that flows per min in a standard state (25° C., 1 atm). Monosilane or the like may also be used instead of dichlorosilane. Also, 30% or less of Ge may be contained in the silicon layer by adding a Ge-containing gas such as GeH₄ to the source gas for film formation.

Chlorine (Cl₂) or the like may be used instead of hydrochloric acid as the halogen gas. It is not always necessary to mix the halogen gas, such as Cl₂ or HCl, when other precursors, such as SiH₂Cl₂, contain halogen.

Mixing of the halogen gas makes it possible to etch defects and dislocations and polysilicon that can be easily etched while forming a thin single-crystal silicon film. Consequently, the crystallinity can improve in a region where single-crystal silicon grows. Also, unintentionally-generated polycrystalline nuclei can be etched on the insulating layer. This effectively improves the selectivity of selective growth.

This vapor phase growth deposits a 10-nm thick thin single-crystal film 19 on the single-crystal silicon region 15, and forms a thin polycrystalline film having a rough surface on the polysilicon region 17.

A MOSFET was formed on the thin single-crystal film thus formed, and the characteristics of this MOSFET were evaluated. As a result, the MOSFET was particularly superior in junction leakage to a device having no single-crystal silicon film 19 formed by vapor phase growth. It is also possible to form a NAND cell on the thin single-crystal film.

This is because many point defects remain in a thin single-crystal silicon film formed by lateral solid phase epitaxy alone since the film is formed at a low temperature, whereas the density of such point detects is low and the density of recombination centers that cause junction leakage is also low in a film formed at a high temperature.

In addition, vapor phase growth improves the surface flatness compared to a thin single-crystal silicon film formed by lateral solid phase epitaxy alone. Accordingly, a thin high-quality silicon film that is advantageous in forming a high-performance device near the surface can be formed by a simple low-cost method compared to a method such as laser annealing.

Note that this embodiment grows the 10-nm thick single-crystal silicon film 19 by vapor phase growth, but the thickness may also be decreased to, e.g., about 2 nm. This is so because carriers flow within the range of at most 1 to 2 nm from the surface in the channel of the MOSFET during the operation of MOSFET.

On the other hand, when the operation of the MOSFET is taken into consideration, the silicon surface is preferably as flat as possible in order to obtain high mobility. To this end, the thin single-crystal silicon film 19 is desirably grown to have a certain thickness, e.g., about 5 nm or more, although it also depends upon the surface flatness of the underlying silicon film 15.

The growth temperature is also not limited to 780° C. because the crystallinity of the vapor phase growth layer 19 becomes better than that of the silicon layer 15 if the temperature is higher than 580° C. at which amorphous silicon is grown.

Furthermore, a film to be grown by vapor phase growth is not limited to the thin silicon film, and may also be an SiGe film (atomic Ge concentration=1% to 40%) or Si:C film (carbon-containing film, atomic C concentration=0.1% to 2%). This is so because the use of an Si film containing an element such as Ge or C as the channel can increase the mobility of the MOSFET.

In particular, the method of this embodiment can form an SiGe film or Si:C film having high crystallinity on the SOI structure.

The film thickness is about 2 to 10 nm in this case as well. It is also possible to successively form an Si film about 1 nm thick on the uppermost surface after the growth of the SiGe film or Si:C film.

Note that after the steps of this embodiment, multiple layers may also be formed by forming an insulating film having an opening and repeating the steps of this embodiment.

### Second Embodiment

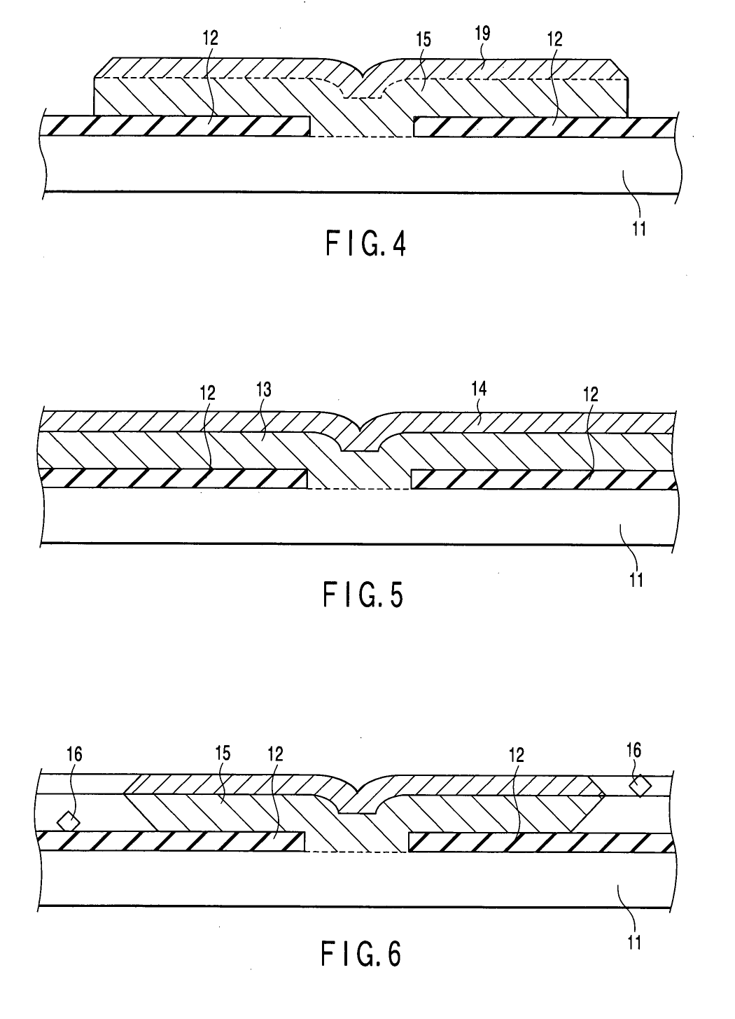

A semiconductor device fabrication method according to the second embodiment of the present invention will be explained below with reference to a sectional view of FIG. 4. This embodiment is obtained by changing the flow rate of hydrochloric acid to 60 sccm as the growth condition of vapor phase growth of silicon in the first embodiment, and is the same as the first embodiment until the step shown in FIG. 2.

As shown in FIG. 4, vapor phase growth of this embodiment forms an vapor phase growth layer 19 not on a polycrystalline but on single-crystal silicon 15 alone, and also etches an originally existing polysilicon layer 17. This makes it possible to obtain a structure in which only the thin single-crystal silicon film 19 is formed.

This is so because the increase in flow rate of hydrochloric acid compared to the first embodiment increases the priority of etching in the relationship between deposition and etching, and as a consequence only the polysilicon region 17 that is easy to be etched is etched. This embodiment can etch single-crystal silicon as described above by changing the flow rate of hydrochloric acid from 40 sccm in the first embodiment to 60 sccm.

The flow rate of hydrochloric acid necessary to achieve this effect is generally obtained as follows. For example, when film formation is performed on a polysilicon film by using a gas system as indicated by this experiment, the dependence of the growth rate on the hydrochloric acid flow rate is measured. The hydrochloric acid flow rate can be determined from the conditions that the growth rate and etching rate are almost equal, i.e., well balanced, and the film thickness of the polysilicon film remains unchanged.

This method can selectively form, only around the opening, a thin single-crystal film having a high-quality, single-crystal silicon layer on its surface.

### Third Embodiment

A semiconductor device fabrication method according to the third embodiment of the present invention will be explained below with reference to sectional views of FIGS. 5 to 9.

First, as shown in FIG. 5, an insulating film 12 as a 10-nm thick silicon oxide film having an opening is formed on the major surface of a silicon substrate 11 (single-crystal silicon) by, e.g., the same method as in the first embodiment.

Then, on the surface of the silicon substrate 11 exposed in the opening and on the surface of the silicon oxide film 12, a 50-nm thick amorphous silicon film 13 is deposited at a deposition temperature of 520° C. by low-pressure CVD using disilane (Si₂H₆).

Successively, 10-nm thick, phosphorus (P)-doped amorphous silicon (phosphorus concentration=1×10²⁰ cm⁻³) 14 is deposited by low-pressure CVD using a gas mixture of silane and phosphine (PH₃) (FIG. 5). When adding boron (B) instead of phosphorus, diborane (B₂H₆) is mixed in silane.

As shown in FIG. 6, the amorphous silicon film 13 is changed into a single crystal by lateral solid phase epitaxy by performing annealing at 620° C. for 30 min. Consequently, the amorphous silicon 13 deposited in and around the opening forms a single-crystal silicon region 15 having the same plane orientation as the substrate by lateral solid phase epitaxy. In addition, single-crystal nuclei 16 randomly form in a region apart from the opening.

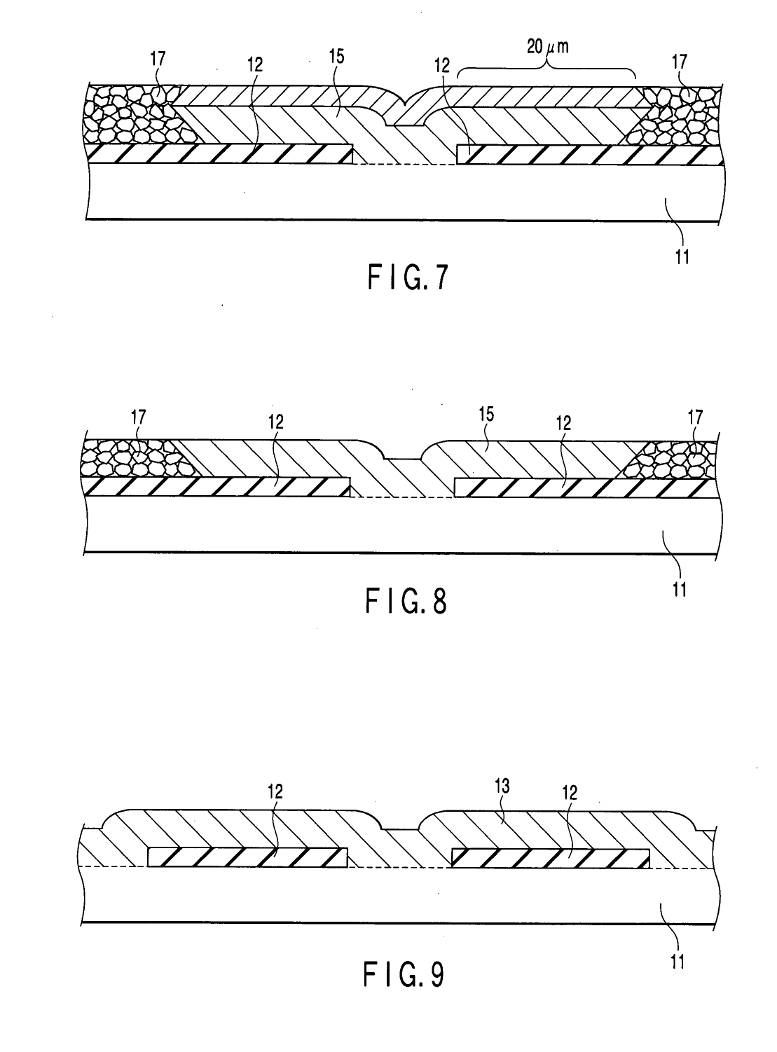

Furthermore, annealing is additionally performed at 620° C. for 30 min. Consequently, as shown in FIG. 7, the region that is not changed into a single crystal finally forms a polysilicon region 17 from the single-crystal nuclei 16 as start points. The size of the single-crystal silicon region 15 formed by lateral solid phase epitaxy is 20 μm from the edge of the opening.

For comparison, the same experiment was conducted without depositing the phosphorus-doped amorphous silicon 14. As a consequence, the size of the single-crystal region formed by lateral solid phase epitaxy was only 5 μm. This difference was produced because the rate of lateral solid phase epitaxy of doped amorphous silicon differs from that of undoped amorphous silicon; the solid phase epitaxial growth rate of doped amorphous silicon is about 10 times higher than that of undoped amorphous silicon.

Subsequently, the phosphorus-doped silicon layer 14 is removed by, e.g., wet etching using dilute fluoronitric acid, etching using a halogen-based gas, or low-temperature radial oxidation, thereby leaving only the undoped single-crystal silicon layer 15 behind as shown in FIG. 8. This makes it possible to form the thin single-crystal silicon film 15 in the 20-μm region around the opening.

After that, the structures shown in FIGS. 3 and 4 can be formed by performing vapor phase growth in the same manner as in the first and second embodiments.

The dopant slightly diffuses from the heavily doped layer to the underlying single-crystal silicon layer. Since the diffusion is isotropic, the surface of the single-crystal silicon layer after the doped layer is etched away is smoother than that of the original single-crystal silicon layer. Accordingly, the surface after vapor phase growth is performed later is also smooth, and this is advantageous in increasing the mobility of a MOSFET.

Note that the deposition of amorphous silicon and the process of changing amorphous silicon into a single crystal by annealing described above may also be successively performed in a reduced pressure ambient without exposing the sample to the atmosphere. Also, when performing etching by using a gas, this etching step may be successively performed.

This embodiment utilizes an amorphous silicon film containing an impurity from the initial stages of lateral solid phase epitaxy, and hence any delay during lateral solid phase epitaxy does not occur. In addition, it is possible to form a large-area, single-crystal layer compared to the case that no impurity-containing amorphous silicon film is formed, and obtain the merits of the first and second embodiments at the same time.

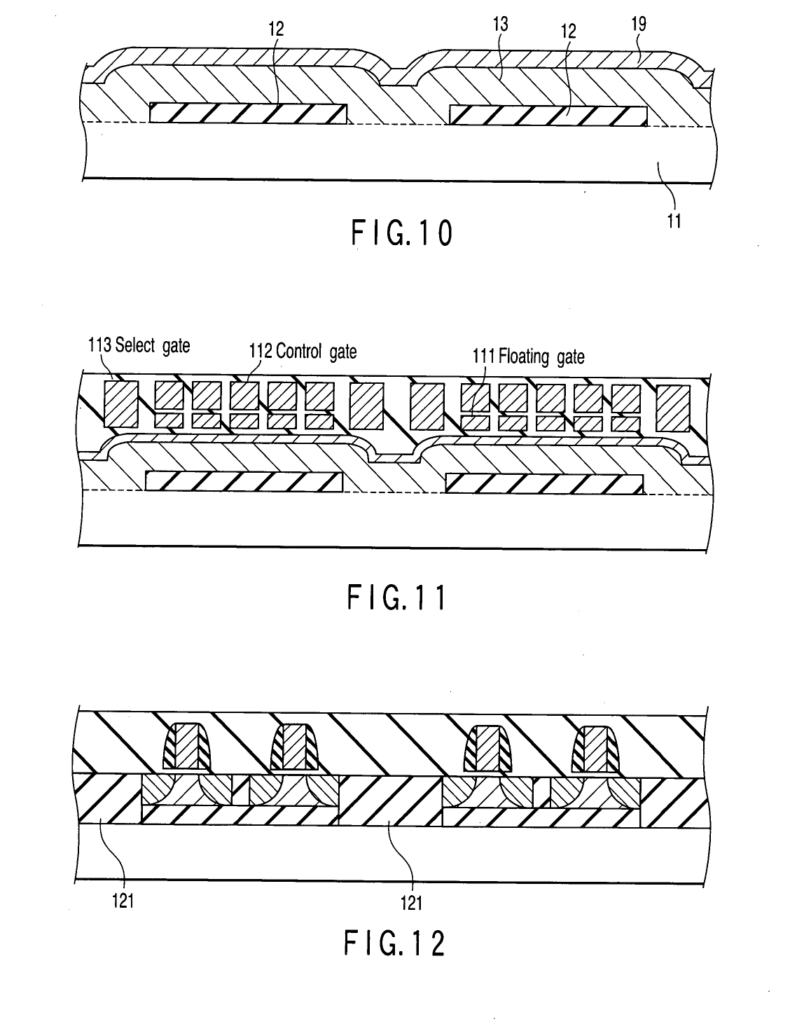

FIGS. 5 to 8 illustrate the case that only one opening is formed in the insulating film 12. As shown in FIG. 9, however, the entire surface of an amorphous silicon film 13 can also be changed into a single crystal by making the distance between openings shorter than the distance at which a single crystal can be formed by lateral solid phase epitaxy. After that, as shown in FIG. 10, a single-crystal silicon film 19 is formed by performing vapor phase growth in the same manner as in the first and second embodiments.

FIG. 11 is a sectional view when a NAND cell is formed by using the structure shown in FIG. 10.

NAND cells having a stacked structure of floating gates 111 as charge storage layers and control gates 112 are formed on a single-crystal layer 19 formed as shown in FIG. 10, thereby forming NAND strings. Select gates 113 are arranged at the two ends of each string. Note that the charge storage layer is not limited to the floating gate but may be an insulating layer such as an SiN layer

In this structure, the NAND cells can be formed on the SOI structure. The SOI as shown in FIG. 10 improves the crystallinity of a channel potion of a cell transistor, and consequently improves the reliability of a tunnel insulating film sandwiched between the channel and floating gate. In addition, a high cell electric current can be obtained because the density of defects in the channel region is low.

FIG. 12 is a sectional view when a MOSFET having the SOI structure is formed using the structure shown in FIG. 10. In this example shown in FIG. 12, two MOSFETs are sandwiched between regions 121 used as seeds. However, the number of MOSFETs can be changed in accordance with the length (area) of an SOI region formed by lateral solid phase epitaxy.

Note that in FIG. 12, after being used as the seeds, the regions 121 are filled with a silicon oxide film in the subsequent step by the well-known isolation method. Therefore, this silicon oxide film separates the underlying silicon substrate and lateral solid phase epitaxially grown region.

Forming a MOSFET on the single-crystal layer 19 having the SOI structure shown in FIG. 10 makes it possible to reduce the leakage current and improve the reliability of the gate insulating film. It is also possible to obtain a high drain current because the density of defects in the channel region is low.

This embodiment uses phosphorus (P) as a dopant impurity. However, it is also possible to use another material such as boron (B), arsenic (As), or antimony (Sb), because the addition of these material increases the solid phase epitaxial-growth rate. The thin silicon film may also contain an element in the same group as silicon. Examples are germanium and carbon.

### Fourth Embodiment

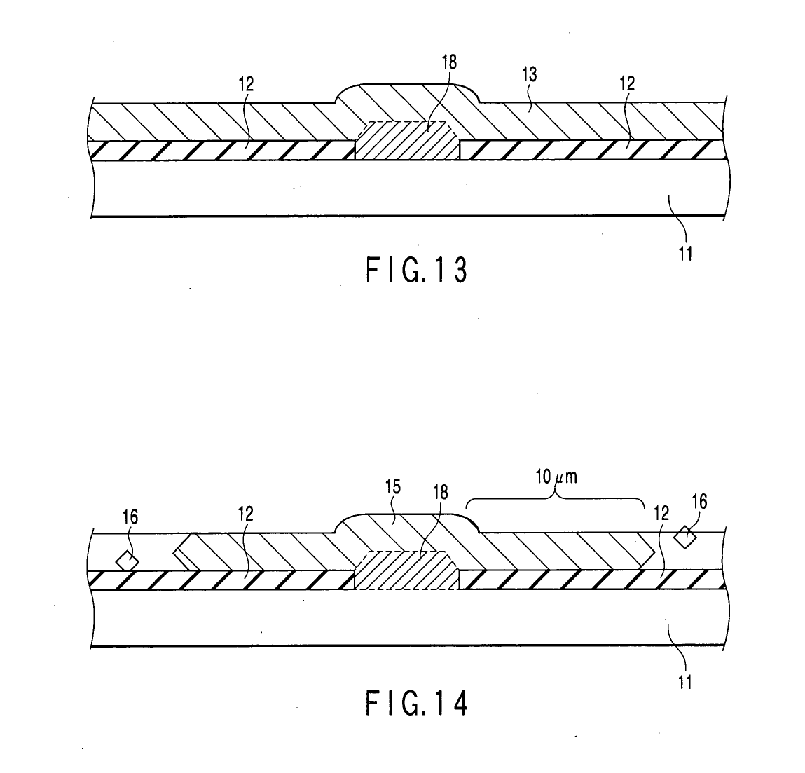

A semiconductor device fabrication method according to the fourth embodiment of the present invention will be explained below with reference to sectional views shown in FIGS. 13 and 14.

First, as shown in FIG. 13, a 10-nm thick insulating film 12 such as a silicon oxide film having an opening is formed on the major surface of a silicon substrate 11 (single-crystal silicon) in the same manner as in the first embodiment.

Then, selective vapor phase growth is performed at, e.g., 850° C. and 10 Torr by using a gas mixture of dichlorosilane and phosphine. This selectively forms phosphorus-doped, single-crystal silicon (phosphorus concentration 2×10²⁰ cm⁻³) 18 on only the silicon substrate 11 (single-crystal silicon) whose surface is exposed in the opening of the insulating film 12.

After that, an undoped amorphous silicon film 13 is deposited on the single-crystal silicon 18 and insulating film 12 by low-pressure CVD using monosilane (FIG. 13).

When the amorphous silicon film 13 around the opening was changed into a single crystal by annealing following the same procedure as in the first to third embodiments, the distance of the single-crystal region was about 10 μm as shown in FIG. 14. As described previously, when the amorphous silicon film 13 alone is formed without forming any phosphorus-doped, single-crystal silicon, the distance from the edge of the opening to the single-crystal region formed by lateral solid phase growth is 5 μm. Therefore, this embodiment almost doubles the lateral solid phase epitaxial-growth distance.

This is so presumably because the impurity-doped, single-crystal silicon 18 is formed to rise in the opening, and this reduces the initial delay time in the process of changing the amorphous silicon film 13 into a single crystal by solid phase growth.

Accordingly, it is also possible to select another material that increases the lateral solid phase epitaxial-growth rate when added as the dopant impurity in this embodiment as well. Examples are boron (B), arsenic (As), and antimony (Sb). When adding boron (B), for example, vapor phase growth is performed by mixing diborane (B₂H₆) in dichlorosilane.

After that, the structures shown in FIGS. 3 and 4 can be formed by performing vapor phase growth in the same manner as in the first and second embodiments. The leakage current can be reduced by forming a MOSFET on the single-crystal silicon film thus formed.

In this embodiment, as in the third embodiment, it is also possible to form a large-area, single-crystal silicon layer by performing annealing after forming an impurity-containing amorphous silicon film on the amorphous silicon film 13. The impurity-containing amorphous silicon film is etched away after the annealing, and the single-crystal silicon layer is formed by vapor phase growth after that, in this case as well. A NAND cell or MOSFET can be formed on this structure following the same procedure as shown in FIGS. 11 and 12 of the third embodiment.

This embodiment makes it possible to form a large-area, single-crystal silicon layer compared to the case that impurity-containing, single-crystal silicon is not formed in the opening, and obtain the merits of the first and second embodiments at the same time. It is also possible to obtain the merit of the third embodiment by performing annealing after forming an impurity-containing amorphous silicon film on the amorphous silicon film 13 in the same manner as in the third embodiment as described above.

Furthermore, single-crystal silicon formed in the opening need not always contain an impurity. In this case, the same effect as in the first, second, or third embodiment can be obtained.

One aspect of the present invention can provide a semiconductor device fabrication method capable of simply forming a thin single-crystal silicon film having high flatness on an insulating film at low cost.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device fabrication method comprising:
forming an insulating film having an opening on a major surface of single-crystal silicon;
forming an amorphous silicon film on a surface of the single-crystal silicon exposed in the opening and on a surface of the insulating film;
performing annealing to change the amorphous silicon film into a single crystal; and
forming one of a single-crystal silicon film, an SiGe film, and a carbon-containing silicon film by vapor phase growth on a region where the amorphous silicon film is changed into a single crystal.

2. A method according to claim 1, wherein the vapor phase growth is performed in an ambient containing a halogen gas, thereby forming one of the single-crystal silicon film, the SiGe film, and the carbon-containing silicon film and etching away a non-single-crystal silicon region at the same time.

3. A method according to claim 2, wherein the halogen gas is one of hydrochloric acid and chlorine.

4. A method according to claim 1, further comprising:
forming an impurity-containing amorphous silicon film on the amorphous silicon film after the formation of the amorphous silicon film and before the annealing; and
removing the impurity-containing silicon film after the annealing and before the vapor phase growth.

5. A method according to claim 1, wherein layers are stacked by repeating the steps.

6. A method according to claim 1, wherein one of a MOSFET and a NAND cell is formed on the single-crystal silicon film formed by the vapor phase growth.

7. A method according to claim 4, wherein one of a MOSFET and a NAND cell is formed on the single-crystal silicon film formed by the vapor phase growth.

8. A semiconductor device fabrication method comprising:
forming an insulating film having an opening on a major surface of single-crystal silicon;
forming a first single-crystal silicon film on a surface of the single-crystal silicon exposed in the opening;
forming an amorphous silicon film on the insulating film and the first single-crystal silicon film;
performing annealing to change the amorphous silicon film into a single crystal; and
forming one of a second single-crystal silicon film, an SiGe film, and a carbon-containing silicon film by vapor phase growth on a region where the amorphous silicon film is changed into a single crystal.

9. A method according to claim 8, wherein when forming the first single-crystal silicon film, an impurity is added to the first single-crystal silicon film.

10. A method according to claim 8, wherein layers are stacked by repeating the steps.

11. A method according to claim 9, wherein a MOSFET is formed on the second single-crystal silicon film formed by the vapor phase growth.

12. A method according to claim 8, wherein the vapor phase growth is performed in an ambient containing a halogen gas, thereby forming one of the second single-crystal silicon film, the SiGe film, and the carbon-containing silicon film and etching away a non-single-crystal silicon region at the same time.

13. A method according to claim 9, wherein the vapor phase growth is performed in an ambient containing a halogen gas, thereby forming one of the second single-crystal silicon film, the SiGe film, and the carbon-containing silicon film and etching away a non-single-crystal silicon region at the same time.

14. A method according to claim 12, wherein the halogen gas is one of hydrochloric acid and chlorine.

15. A method according to claim 13, wherein the halogen gas is one of hydrochloric acid and chlorine.

16. A method according to claim 8, further comprising:
forming an impurity-containing amorphous silicon film on the amorphous silicon film after the formation of the amorphous silicon film and before the annealing; and
removing the impurity-containing silicon film after the annealing and before the vapor phase growth.

17. A method according to claim 9, further comprising:
forming an amorphous silicon film containing a different impurity on the amorphous silicon film after the formation of the amorphous silicon film and before the annealing; and
removing the silicon film containing the different impurity after the annealing and before the vapor phase growth.

18. A method according to claim 16, wherein one of a MOSFET and a NAND cell is formed on the second single-crystal silicon film formed by the vapor phase growth.

19. A method according to claim 17, wherein one of a MOSFET and a NAND cell is formed on the second single-crystal silicon film formed by the vapor phase growth.

20. A method according to claim 17, wherein the different impurity is one of phosphorus (P), boron (B), arsenic (As), and antimony (Sb).
